(19) United States
(12) Patent Application Publication
(10) Pub. No.: US 2025/0113551 A1
(43) Pub. Date: Apr. 3, 2025

(54) FIELD EFFECT TRANSISTOR WITH RECRYSTALLIZED SOURCE/DRAINS AND METHOD

(71) Applicant: Taiwan Semiconductor Manufacturing Co., Ltd., Hsinchu (TW)

(72) Inventors: Chia-Cheng CHEN, Hsinchu (TW); Sih-Jie LIU, Hsinchu (TW); Liang-Yin CHEN, Hsinchu (TW); Chi On CHUI, Hsinchu (TW)

(21) Appl. No.: 18/404,785

(22) Filed: Jan. 4, 2024

Related U.S. Application Data
(60) Provisional application No. 63/587,481, filed on Oct. 3, 2023.

(51) Int. Cl. H01L 29/78; H01L 21/265; H01L 29/06; H01L 29/08; H01L 29/423; H01L 29/66; H01L 29/775

(52) U.S. Cl. CPC H10D 30/796; H01L 21/26526; H10D 30/014; H10D 30/43; H10D 30/6735; H10D 62/121; H10D 62/151; H10D 64/017

(57) ABSTRACT

A method includes: forming a stack of nanostructures over a substrate; forming a source/drain opening adjacent the stack of nanostructures; forming a semiconductor layer in the source/drain opening; forming an amorphous semiconductor layer by performing an ion implantation on the semiconductor layer; and forming a recrystallized source/drain by annealing the amorphous semiconductor layer.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrammatic cross-sectional side views of a portion of an IC device according to embodiments of the present disclosure.

FIGS. 2A-12 are views of various embodiments of an IC device of at various stages of fabrication according to various aspects of the present disclosure.

FIG. 13 is a flowchart of a method of forming an IC device in accordance with various embodiments.

FIG. 14 is a flowchart of a method of forming an IC device having regrown source/drains in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The terms “first,” “second,” “third” and so on may be used herein to describe a sequence of events or sequential order of elements but may be exchanged or varied in some contexts. For example, a second layer may be formed on (e.g., sequentially after) a first layer, but in some contexts the first layer may be referred to as a “second layer,” “third layer,” “fourth layer” or the like, and the second layer may be referred to as a “first layer,” “third layer,” “fourth layer,” or the like.

The term “surrounds” may be used herein to describe a structure that fully or partially encloses another element or structure, for example, in three dimensions. For example, a first structure may “surround” a second structure on four lateral sides (e.g., left, right, front and back) without surrounding the second structure on two vertical sides (e.g., top and bottom). In other example, the first structure may wrap partially around the second structure, for example, by wrapping around three sides (e.g., top, front and back) while leaving other sides (e.g., left, right and bottom) exposed.

The present disclosure is generally related to semiconductor devices, and more particularly to field-effect transistors (FETs), such as planar FETs, three-dimensional fin FETs (FinFETs), or nanostructure FETs, such as nanosheet FETs (NSFETs), nanowire FETs (NWFETs), gate-all-around FETs (GAAFETs) and the like.

Defects can cause source-drain epitaxy strain relaxing, which can result in on current versus off current (e.g., Iₒₙ-I_{off}) degradation in nanosheet devices. One observed defect source is (111) or other direction stacking faults. A material of the source/drain may also have high resistance due to insufficient dopant activation. Processes for forming source/drains can lack selectivity of process conditions by which source/drain strain can be recovered and dopant activation improved.

Embodiments of the disclosure form an amorphized source/drain epitaxy followed by solid-phase epitaxy regrowth (SPER) that regrows or recrystallizes the amorphous source/drain epitaxy to form a source/drain. Amorphization of the source/drain epitaxy can be via ion implantation or via introducing post source-drain epitaxy materials that form a substantially fully amorphous source-drain material. Subsequent anneal processes result in SPER that regrows or recrystallizes the amorphous source/drain material. The SPER can be performed prior to contact etch stop layer (CESL) formation, interlayer dielectric (ILD) formation and/or replacement gate formation in a single anneal or multiple anneals. The SPER may be performed alternatively or additionally as part of thermal budget during or following the formation of the CESL, ILD and replacement gate.

The embodiments are associated with benefits. The SPER operation is selected to eliminate defects and recover strain of source/drain materials. This is due at least to SPER being one order faster along the (100) direction than along the (111) direction. Performing SPER on the amorphous source/drain material to regrow or recrystallize the amorphous source/drain material can result in recovered strain of the source/drain materials on neighboring channels due to stacking fault reduction. The recovery may be selected by a combination of amorphization ion implantation and annealing processes. The amorphization ion implantation can eliminate or reduce the defects (e.g., (111) stacking fault defects) generated during epitaxial growth prior to the annealing process. Performing SPER can increase dopant activation, which can be an additional selection for improving Iₒₙ-I_{off} performance and source/drain resistance of nanosheet devices. The amorphization ion implantation and annealing processes can enhance the strain of the source/drain region, thereby improving electrical performance of channels.

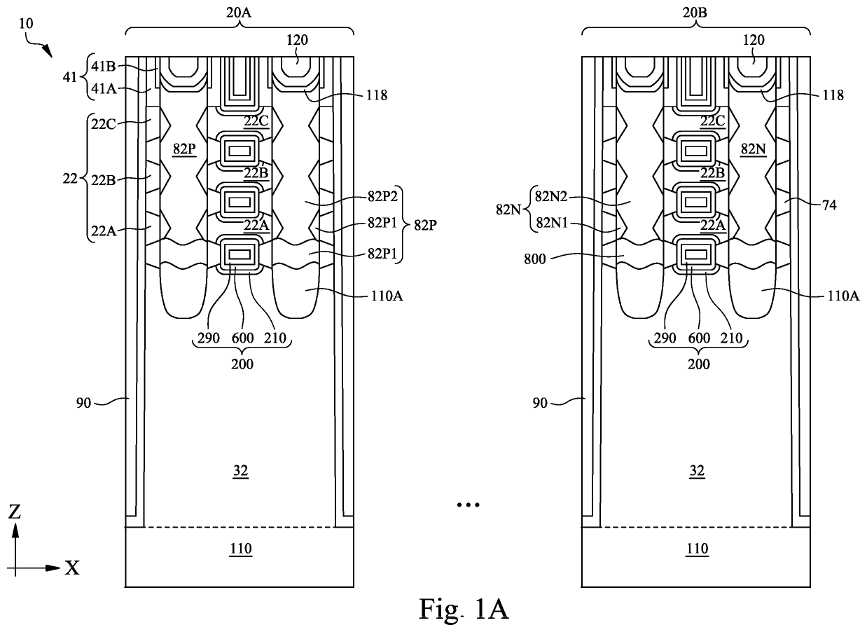

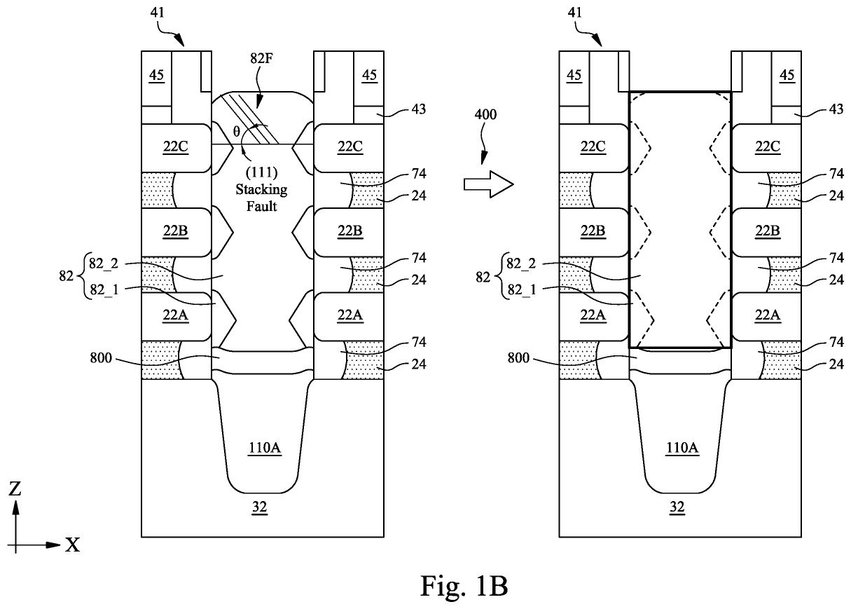

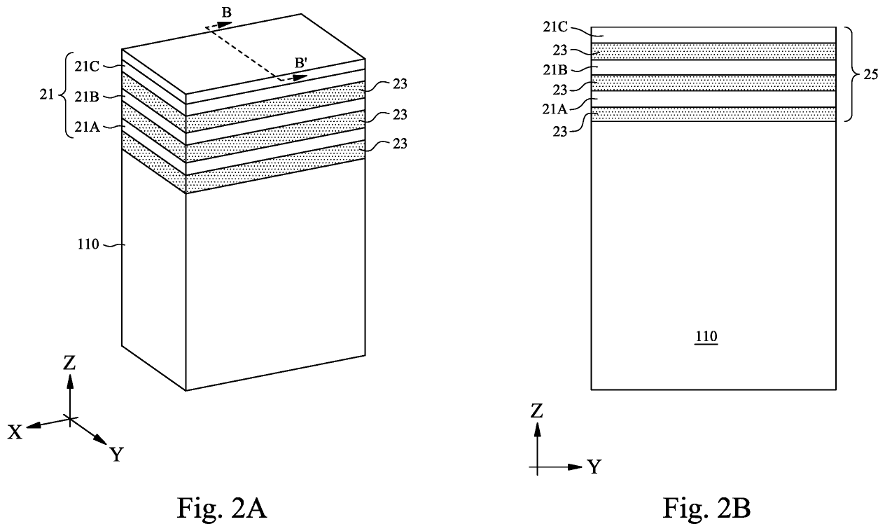

FIG. 1A illustrates a diagrammatic cross-sectional side view of a portion of a nanostructure device 10 in accordance with various embodiments. FIG. 1A illustrates a view in an X-Z plane. The nanostructure device 10 of FIG. 1A is described in detail below to provide context for understanding the technical features and benefits of the various embodiments depicted in FIGS. 2A-12. The nanostructure device 10 includes source/drain regions (or “source/drains”) 82P, 82N that may be substantially free of or have reduced number of stacking fault defects due to a SPER performed during and/or after formation of the source/drain regions. Source/drain region(s) may refer to a source or a drain, individually or collectively dependent upon the context. Although the nanostructure device 10 is described with reference to nanosheet transistors (or “nanostructure devices” 20A, 20B), it should be understood that the embodiments may also include planar field effect transistors (FETs), fin-type FETs (or FinFETs), or the like, each of which may include source/drain regions that have undergone SPER as will be described with reference to FIGS. 1A-12.

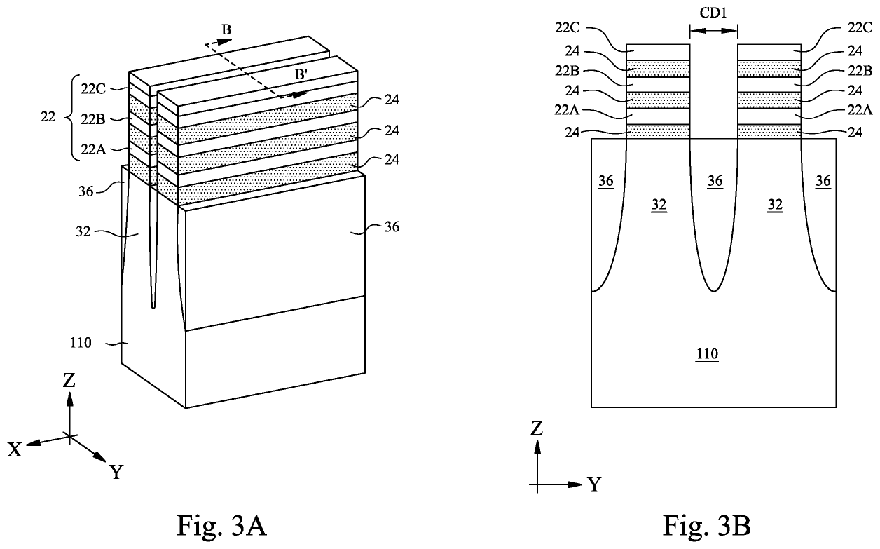

Referring to FIG. 1A, nanostructure devices 20A, 20B may be or include one or more N-type FETs (NFETs) or P-type FETs (PFETs). The nanostructure devices 20A, 20B are formed over and/or in a substrate 110, and generally include gate structures 200 straddling and/or wrapping around semiconductor channels 22A, 22B, 22C, alternately referred to as “nanostructures,” located over semiconductor fins 32 protruding from, and separated by, isolation structures 36 (see FIG. 3B). The gate structure 200 controls electrical current flow through the channels 22A, 22B, 22C.

The nanostructure devices 20A, 20B are shown including three channels 22A, 22B, 22C, which are laterally abutted by source/drain features 82N, 82P, and covered and surrounded by the gate structure 200. Generally, the number of channels 22 is two or more, such as three or four or more. The gate structure 200 controls flow of electrical current through the channels 22A, 22B, 22C to and from the source/drain features 82N, 82P based on voltages applied at the gate structure 200 and at the source/drain features 82N, 82P. The source/drain features 82N, 82P may alternately be referred to as source/drain features 82.

In some embodiments, the fin structure 32 includes silicon. In some embodiments, the nanostructure device 20B includes an NFET, and the source/drain features 82N thereof include silicon phosphorous (SiP), SiAs, SiSb, SiPAs, SiP: As: Sb, combinations thereof, or the like. In some embodiments, the nanostructure device 20A includes a PFET, and the source/drain features 82P thereof include silicon germanium (SiGe), either undoped or doped to form, for example, SiGe: B, SiGe: B: Ga, SiGe: Sn, SiGe: B: Sn, or another appropriate semiconductor material. Generally, the source/drain features 82N, 82P may include any combination of appropriate semiconductor material(s) and appropriate dopant(s). In some embodiments, the source/drain features 82N, 82P include SiₓC_{y}, SiₓGe_{y}, SiₓSb_{y}, SiₓP_{y}, SiₓAs_{y}, where 0<x<1 and 0<y<1, as appropriate.

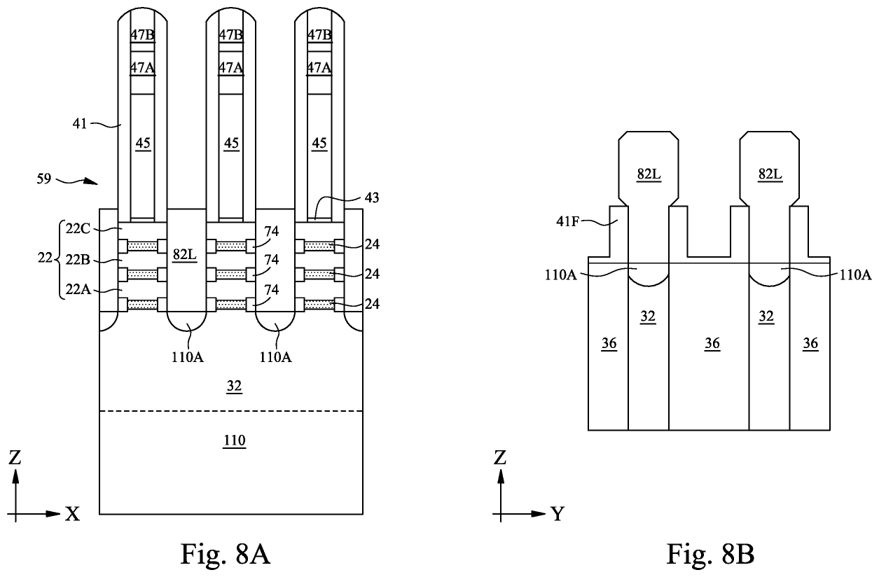

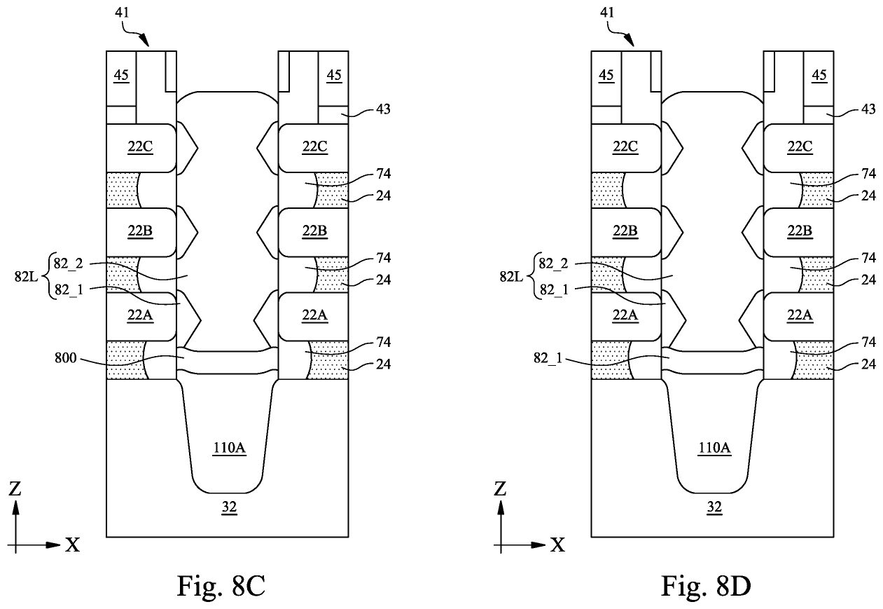

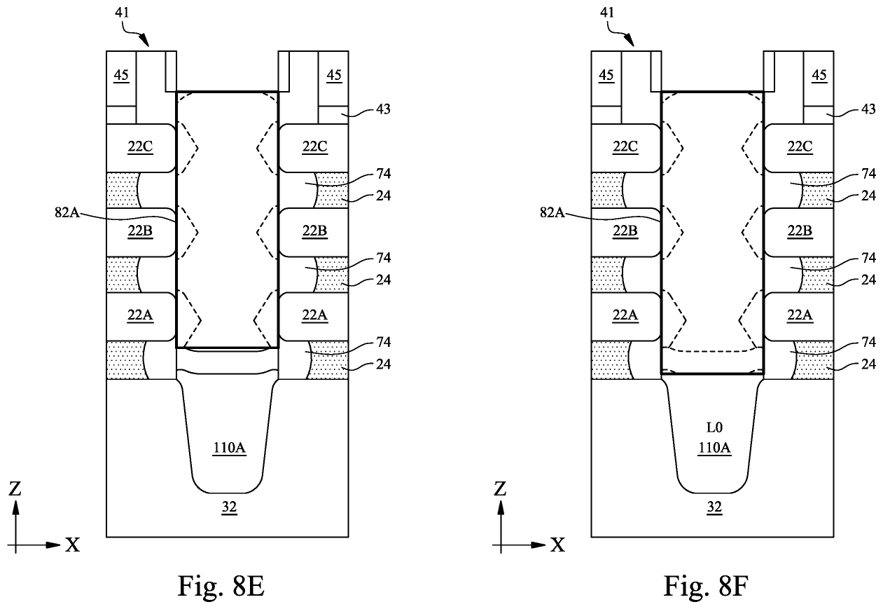

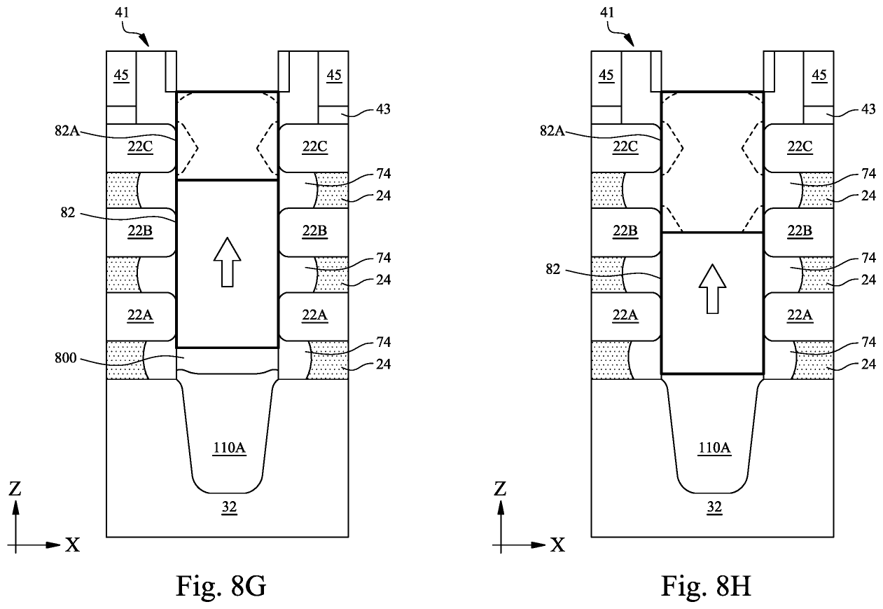

In some embodiments, the source/drain features 82N, 82P may include one or more implanted ions, which may be or include one or more species, such as group Ill species including B, Al, Ga, group IV including C, Si, Ge, group V species including P, As, Sb, group VIII species including He, Ar, Xe, combinations thereof and the like. As will be described with reference to FIGS. 8A-8H, the ions may be implanted with implantation energy in a range of about 1 kilo-electron-volt (keV) to about 60 keV. In some embodiments, implantation dosage of the ions exceeds about 1×10¹³ cm⁻², such as in a range of about 1×10¹³ cm⁻² to about 1×10²² cm⁻². In some embodiments, the dosage of group III and/or group V species is in a range of about 1×10¹⁹ cm⁻² to about 1×10²² cm⁻², which is beneficial to improve SPER rate. Above about 1×10²² cm⁻², the SPER rate may be reduced. Implantation temperature may be in a range of about −150° C. to about 500° C. In some embodiments, the implantation temperature is room temperature. Higher temperature, such as above about 500° C., can reduce defect generation during the implantation process. Temperatures in the cryogenic range can improve formation of amorphous source/drain material. “High temperature cryogenics” can refer to a range of about −50° C. to about-195.79° C. and “low temperature cryogenics” can refer to temperatures below about −195.79° C. The cryogenic range can include high temperature cryogenics, low temperature cryogenics, or the combination thereof.

The channels 22A, 22B, 22C each include a semiconductive material, for example silicon or a silicon compound, such as silicon germanium, or the like. The channels 22A, 22B, 22C are nanostructures (e.g., having sizes that are in a range of a few nanometers) and may also each have an elongated shape and extend in the X-direction. In some embodiments, the channels 22A, 22B, 22C each have a nanowire (NW) shape, a nanosheet (NS) shape, a nanotube (NT) shape, or other suitable nanoscale shape. The cross-sectional profile of the channels 22A, 22B, 22C may be rectangular, round, square, circular, elliptical, hexagonal, or combinations thereof.

In some embodiments, the lengths (e.g., measured in the X-direction) of the channels 22A, 22B, 22C may be different from each other, for example due to tapering during a fin etching process (see FIGS. 3A, 3B). In some embodiments, length of the channel 22C may be less than a length of the channel 22B, which may be less than a length of channel 22A. The channels 22A, 22B, 22C each may not have uniform thickness (e.g., along the X-axis direction), for example due to a channel trimming process used to expand spacing (e.g., measured in the Z-axis direction) between the channels 22A, 22B, 22C to increase gate structure fabrication process window. For example, a middle portion of each of the channels 22A, 22B, 22C may be thinner than the two ends of each of the channels 22A, 22B, 22C. Such shape may be collectively referred to as a “dog-bone” shape.

In some embodiments, the spacing between the channels 22A, 22B, 22C (e.g., between the channel 22B and the channel 22A or the channel 22C) is in a range between about 8 nanometers (nm) and about 12 nm, though ranges exceeding or below the said range may also be beneficial. In some embodiments, a thickness (e.g., measured in the Z-direction) of each of the channels 22A, 22B, 22C is in a range between about 5 nm and about 8 nm, though ranges exceeding or below the said range may also be beneficial. In some embodiments, a width (e.g., measured in the Y-direction, shown in FIG. 1E, orthogonal to the X-Z plane) of each of the channels 22A, 22B, 22C is at least about 8 nm, however the width may be less than 8 nm in some embodiments.

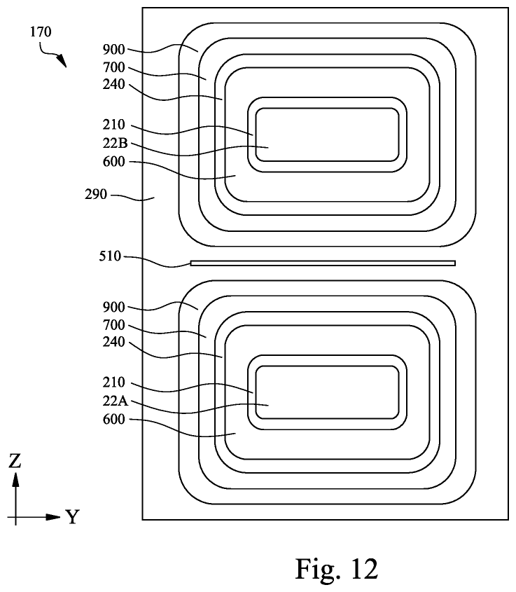

The gate structure 200 is disposed over and between the channels 22A, 22B, 22C, respectively. In some embodiments, the gate structure 200 is disposed over and between the channels 22A, 22B, 22C, which are silicon channels for N-type devices or silicon germanium channels for P-type devices. In some embodiments, the gate structure 200 includes an interfacial layer (IL) 210, one or more gate dielectric layers 600 on the interfacial layer 210, optionally one or more work function tuning layers 900 (see FIG. 12) on the gate dielectric layer 600 and a metal core layer 290 on the gate dielectric layer 600 and optionally on the work function tuning layer 900.

The interfacial layer 210, which may be an oxide of the material of the channels 22A, 22B, 22C, is formed on exposed areas of the channels 22A, 22B, 22C and the top surface of the fin 32. The interfacial layer 210 promotes adhesion of the gate dielectric layers 600 to the channels 22A, 22B, 22C. In some embodiments, the interfacial layer 210 has thickness of about 5 Angstroms (Å) to about 50 Angstroms (Å). In some embodiments, the interfacial layer 210 has thickness of about 10 A. The interfacial layer 210 having thickness that is too thin may exhibit voids or insufficient adhesion properties. The interfacial layer 210 being too thick consumes gate fill window, which is related to threshold voltage tuning and resistance. In some embodiments, the interfacial layer 210 is doped with a dipole, such as lanthanum, for threshold voltage tuning.

In some embodiments, the gate dielectric layer 600 includes at least one high-k gate dielectric material, which may refer to dielectric materials having a high dielectric constant that is greater than a dielectric constant of silicon oxide (k≈3.9). Example high-k dielectric materials include HfO₂, HfSiO, HfSiON, HfTaO, HfTiO, HfZrO, ZrO₂, Ta₂O₅, or combinations thereof. In some embodiments, the gate dielectric layer 600 has thickness of about 5 Å to about 100 A. The gate dielectric layer 600 may be a single layer or a multilayer.

The gate structure 200 also includes metal core layer 290. The metal core layer 290 may include a conductive material such as Co, W, Ru, combinations thereof, or the like. In some embodiments, the metal core layer 290 is or includes a Co-, W- or Ru-based compound or alloy including one or more elements, such as Zr, Sn, Ag, Cu, Au, Al, Ca, Be, Mg, Rh, Na, Ir, W, Mo, Zn, Ni, K, Co, Cd, Ru, In, Os, Si, Ge, Mn, combinations thereof, or the like. Between the channels 22A, 22B, 22C, the metal core layer 290 is circumferentially surrounded (in the cross-sectional view) by the one or more work function metal layers 900, which are then circumferentially surrounded by the gate dielectric layers 600, which are circumferentially surrounded by the interfacial layer 210. The gate structure 200 may also include a glue layer that is formed between the one or more work function layers 900 and the metal core layer 290 to increase adhesion. The glue layer is not specifically illustrated in FIG. 1A for simplicity.

The nanostructure devices 20A, 20B may further include source/drain contacts 120 that are formed over the source/drain features 82N, 82P. The source/drain contacts 120 may include a core layer that is or includes a conductive material such as tungsten, ruthenium, cobalt, copper, titanium, titanium nitride, tantalum, tantalum nitride, iridium, molybdenum, nickel, aluminum, or combinations thereof. The core layer may be surrounded by one or more liner (or, “barrier”) layers, such as SiN or TiN, which help prevent or reduce diffusion of materials from and into the source/drain contacts 120. In some embodiments, height of the source/drain contacts 120 may be in a range of about 1 nm to about 50 nm.

Silicide layers 118 are positioned between the source/drain features 82N, 82P and the source/drain contacts 120, at least to reduce the source/drain contact resistance. In some embodiments, the silicide layer 118 is or includes TiSi, CrSi, TaSi, MoSi, ZrSi, HfSi, ScSi, Ysi, HoSi, TbSI, GdSi, LuSi, DySi, ErSi, YbSi, or the like. In some embodiments, the silicide layer 118 is or includes NiSi, CoSi, MnSi, Wsi, FeSi, RhSi, PdSi, RuSi, PtSi, IrSi, OsSi, or the like. The silicide layer 118 may have thickness in a range of about 1 nm to about 10 nm. Thickness lower than about 1 nm may lead to an insufficient reduction in contact resistance. Thickness above about 10 nm may cause electrical shorting with the nanostructures 22. In some embodiments, the silicide layer 118 is present below, and in contact with, etch stop layer 131.

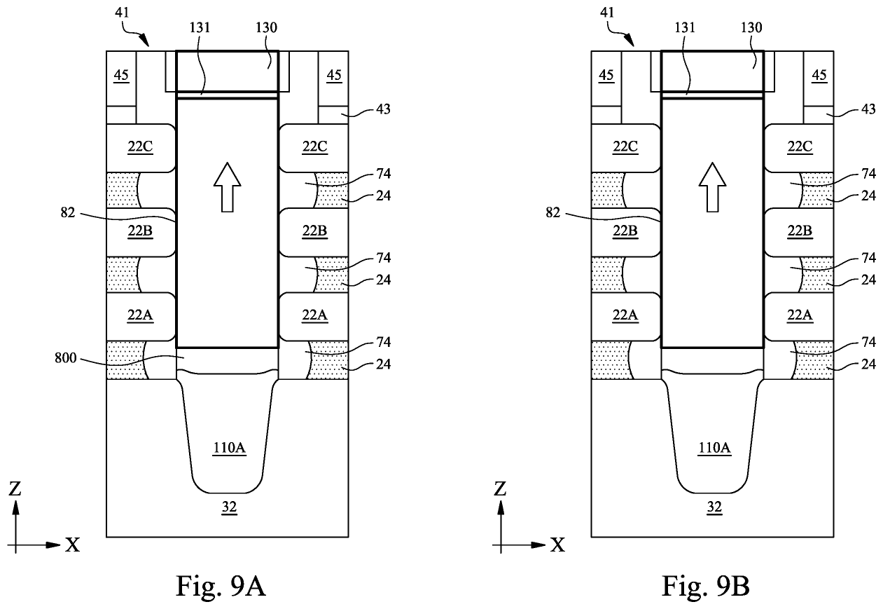

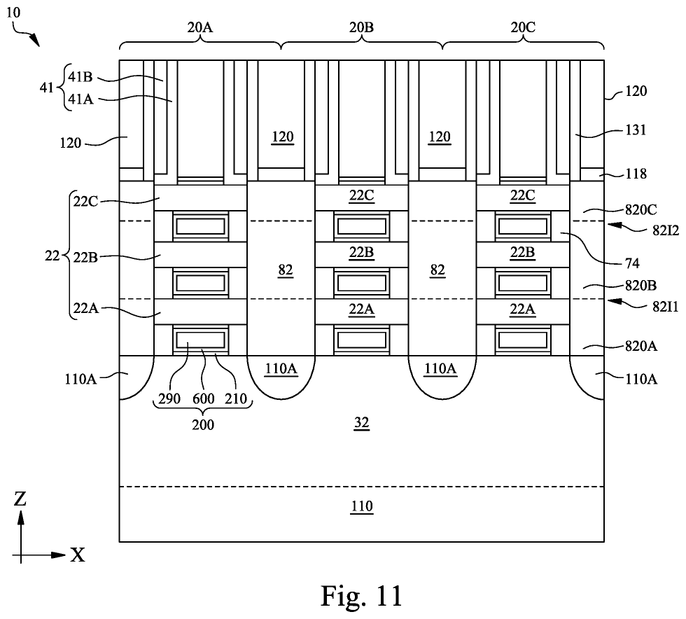

The nanostructure devices 20A, 20B may further include an interlayer dielectric 130 (ILD; see FIGS. 9A, 9B). The ILD 130 provides electrical isolation between the various components of the nanostructure devices 20A, 20B discussed above, for example between neighboring pairs of the source/drain contacts 120. An etch stop layer 131 (see FIG. 11) may be formed prior to forming the ILD 130 and may be positioned laterally between the ILD 130 and the gate spacers 41 and vertically between the ILD 130 and the source/drain features 82N, 82P. In some embodiments, the etch stop layer 131 is or includes SiN, SiCN, SiC, SiOC, SiOCN, HfO2, ZrO2, ZrAlOx, HfAlOx, HfSiOx, Al2O3, or other suitable material. In some embodiments, thickness of the etch stop layer is in a range of about 1 nm to about 5 nm. In some embodiments, where the ILD 130 is not present (e.g., is removed completely prior to formation of the source/drain contacts 120), the etch stop layer 131 may be in contact with the source/drain contact 120. The etch stop layer 131 may be trimmed, for example, in the X-axis direction prior to formation of the source/drain contact 120 to improve fill quality of the source/drain contact 120.

The nanostructure devices 20A, 20B include gate spacers 41 that are disposed on sidewalls of the metal core layer 290, the gate dielectric layer 600 and the IL 210 above the channel 22A, and inner spacers 74 that are disposed on sidewalls of the IL 210 and/or the gate dielectric layer 600 between the channels 22A, 22B, 22C. The inner spacers 74 are also disposed between the channels 22A, 22B, 22C. In the embodiment depicted in FIG. 1A, the gate spacers 41 include a first spacer layer 41A and a second spacer layer 41B on the first spacer layer 41A. The first and second spacer layers 41A, 41B may each include a dielectric material, for example a low-k material such as SiOCN, SiON, SiN, SiCN, SiOC or the like. In some embodiments, the second spacer layer 41B is not present. Material of the first and second spacer layers 41A, 41B may be the same as or different from each other. In some embodiments, an upper portion of the second spacer layer 41B (or the first spacer layer 41A when the second spacer layer 41B is not present) may be removed partially or fully to increase aspect ratio of an opening through which the source/drain region 82N, 82P is formed. FIG. 1A depicts an embodiment in which the upper portion of the second spacer layer 41B is not thinned.

An isolation structure 90 may be positioned on either side of the respective nanostructure device 20A, 20B. In some embodiments, the isolation structure 90 extends from a level below a bottom surface of the source/drain(s) 82N, 82P to a level above an upper surface of the source/drain(s) 82N, 82P. The isolation structure 90 may include one or more dielectric layers that provide physical and/or electrical isolation between the nanostructure devices 20A, 20B and adjacent devices. In some embodiments, the isolation structure(s) 90 is not present.

In FIG. 1A, the nanostructure devices 20A, 20B are depicted as being positioned on a same substrate 110 and on different regions of the substrate 110, for example, offset from each other on the substrate 110. In some embodiments, the nanostructure device 20A is a p-type field effect transistor (PFET) and the nanostructure device 20B is an n-type field effect transistor (NFET). In some embodiments, the nanostructure device 20B includes a dielectric layer 800 that isolates the source/drain 82N from the underlying substrate 110 or fin 32. The dielectric layer 800 may be referred to as a flexible bottom insulator (FBI), bottom dielectric isolation (BDI), or the like.

In FIG. 1A, the source/drain 82P may include first source/drain portions 82P1 and a second source/drain portion 82P2 on the first source/drain portions 82P1. The first source/drain portions 82P1 are adjacent to an undoped semiconductor layer 110A that underlies the source/drain 82P and the channels 22. The second source/drain portion 82P2 is positioned on the first source/drain portions 82P1. Visible interfaces may be present between the first and second source/drain portions 82P1, 82P2. In some embodiments, the first and second source/drain portions 82P1, 82P2 are different in one or more respects. For example, the first and second source/drain portions 82P1, 82P2 may have different materials from each other, such as different dopant concentrations from each other. In some embodiments, the first and second source/drain portions 82P1, 82P2 are substantially the same materials but have different crystal orientations due to being formed in different epitaxial growth operations.

The source/drain 82N may include first source/drain portions 82N1 and a second source/drain portion 82N2 on the first source/drain portions 82N1. The first source/drain portions 82N1 are adjacent to the channels 22. The second source/drain portion 82N2 is positioned on the first source/drain portions 82N1 and the dielectric layer 800. Visible interfaces may be present between the first and second source/drain portions 82N1, 82N2. In some embodiments, the first and second source/drain portions 82N1, 82N2 are different in one or more respects. For example, the first and second source/drain portions 82N1, 82N2 may have different materials from each other, such as different dopant concentrations from each other. In some embodiments, the first and second source/drain portions 82N1, 82N2 are substantially the same materials but have different crystal orientations due to being formed in different epitaxial growth operations.

FIG. 1B depicts a simplified diagram of a process 400 for regrowing or recrystallizing a source/drain 82 in accordance with various embodiments.

In FIG. 1B, a source/drain 82 includes first portions 82_1 and second portion 82_2 on the first portions 82_1. The first portions 82_1 may be an embodiment of the first source/drain portions 82N1, 82P1 and the second portions 82_2 may be an embodiment of the second source/drain portions 82N2, 82P2. The dielectric layer 800 is depicted in FIG. 1B but may be omitted in some embodiments.

The source/drain 82 may include one or more stacking faults 82F, which may be (111) direction stacking faults 82F. The stacking faults 82F may be oriented at an offset angle θ, which may be about 54.7° from horizontal or about 35.3° from vertical.

In the process 400, the source/drain 82 may be amorphized, then a solid-phase epitaxy regrowth (SPER) may be performed via one or more annealings that recrystallizes the source/drain 82, thereby removing the stacking faults 82F.

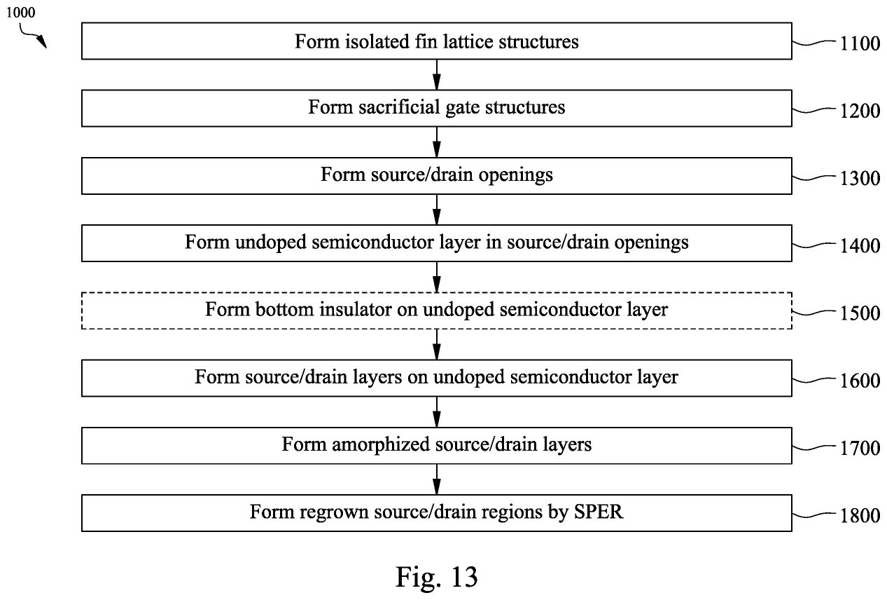

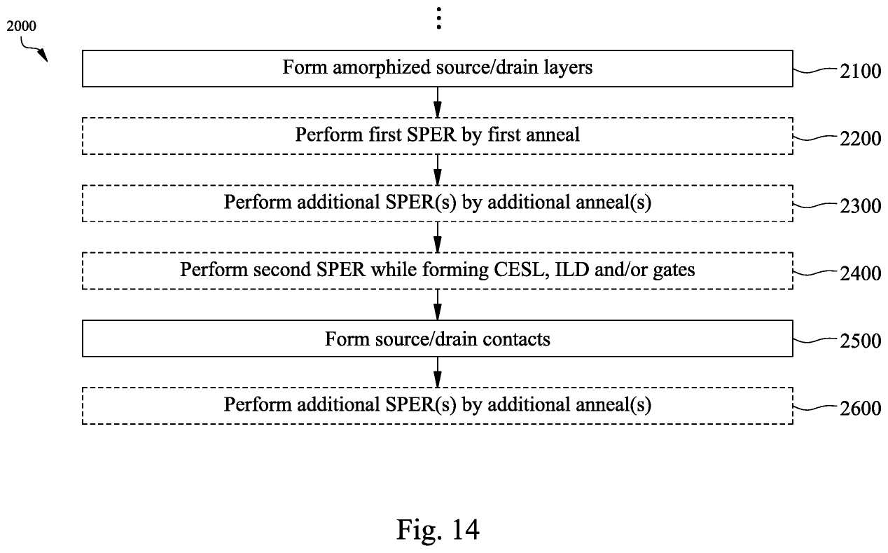

Embodiments of the process 400 are described in greater detail with reference to methods 1000, 2000 depicted in FIGS. 13 and 14 and diagrams of a device 10 at intermediate stages of processing depicted in FIGS. 2A-12.

FIGS. 13 and 14 depict flowcharts of methods 1000, 2000 for forming an IC device or a portion thereof from a workpiece, according to one or more aspects of the present disclosure. Methods 1000, 2000 are merely examples and not intended to limit the present disclosure to what is explicitly illustrated in methods 1000, 2000. Additional acts can be provided before, during and after the methods 1000, 2000 and some acts described can be replaced, eliminated, or moved around for additional embodiments of the method. Not all acts are described herein in detail for reasons of simplicity. Methods 1000, 2000 are described below in conjunction with fragmentary perspective and/or cross-sectional views of a workpiece, shown in FIGS. 2A-12, at different stages of fabrication according to embodiments of methods 1000, 2000. For avoidance of doubt, throughout the figures, the X direction is perpendicular to the Y direction and the Z direction is perpendicular to both the X direction and the Y direction. It is noted that, because the workpiece may be fabricated into a semiconductor device, the workpiece may be referred to as the semiconductor device as the context requires.

FIGS. 2A through 12 are views of intermediate stages in the manufacturing of FETs, such as nanostructure FETs, in accordance with some embodiments.

In FIG. 2A and FIG. 2B, a substrate 110 is provided. The substrate 110 may be a semiconductor substrate, such as a bulk semiconductor, or the like, which may be doped (e.g., with a p-type or an n-type dopant) or undoped. The semiconductor material of the substrate 110 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

Further in FIG. 2A and FIG. 2B, a multi-layer stack 25 or “lattice” is formed over the substrate 110 of alternating layers of first semiconductor layers 21A, 21B (collectively referred to as first semiconductor layers 21) and second semiconductor layers 23. In some embodiments, the first semiconductor layers 21 may be formed of a first semiconductor material suitable for n-type nano-FETs, such as silicon, silicon carbide, or the like, and the second semiconductor layers 23 may be formed of a second semiconductor material suitable for p-type nano-FETs, such as silicon germanium or the like. Each of the layers 21, 23 of the multi-layer stack 25 may be epitaxially grown using a process such as chemical vapor deposition (CVD), atomic layer deposition (ALD), vapor phase epitaxy (VPE), molecular beam epitaxy (MBE), or the like.

Three layers of each of the first semiconductor layers 21 and the second semiconductor layers 23 are illustrated. In some embodiments, the multi-layer stack 25 may include fewer or additional pairs of the first semiconductor layers 21 and the second semiconductor layers 23. Although the multi-layer stack 25 is illustrated as including a second semiconductor layer 23 as the bottommost layer, in some embodiments, the bottommost layer of the multi-layer stack 25 may be a first semiconductor layer 21.

Due to high etch selectivity between the first semiconductor materials and the second semiconductor materials, the second semiconductor layers 23 of the second semiconductor material may be removed without significantly removing the first semiconductor layers 21 of the first semiconductor material, thereby allowing the first semiconductor layers 21 to be patterned to form channel regions of nano-FETs. In some embodiments, the first semiconductor layers 21 are removed and the second semiconductor layers 23 are patterned to form channel regions. The high etch selectivity allows the first semiconductor layers 21 of the first semiconductor material to be removed without significantly removing the second semiconductor layers 23 of the second semiconductor material, thereby allowing the second semiconductor layers 23 to be patterned to form channel regions of nano-FETs.

In FIG. 3A and FIG. 3B, fins 32 are formed in the substrate 110 and nanostructures 22, 24 are formed in the multi-layer stack 25 corresponding to act 1100 of FIG. 13. In some embodiments, the nanostructures 22, 24 and the fins 32 may be formed by etching trenches in the multi-layer stack 25 and the substrate 110. The etching may be any acceptable etch process, such as a reactive ion etch (RIE), neutral beam etch (NBE), the like, or a combination thereof. The etching may be anisotropic. First nanostructures 22A, 22B, 22C (also referred to as “channels 22” below) are formed from the first semiconductor layers 21, and second nanostructures 24 are formed from the second semiconductor layers 23. Distance CD1 between adjacent fins 32 and nanostructures 22, 24 may be from about 18 nm to about 100 nm, though distances CD1 that are smaller than 18 nm may be beneficial in some embodiments. A portion of the device 10 is illustrated in FIGS. 3A and 3B including two fins 32 for simplicity of illustration. The process 1000 illustrated in FIG. 13 may be extended to any number of fins, and is not limited to the two fins 32 shown in FIGS. 3A-12.

The fins 32 and the nanostructures 22, 24 may be patterned by any suitable method. For example, one or more photolithography processes, including double-patterning or multi-patterning processes, may be used to form the fins 32 and the nanostructures 22, 24. Generally, double-patterning or multi-patterning processes combine photolithography and self-aligned processes, allowing for pitches smaller than what is otherwise obtainable using a single, direct photolithography process. As an example of one multi-patterning process, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the fins 32.

FIGS. 3A and 3B illustrate the fins 32 having tapered sidewalls, such that a width of each of the fins 32 and/or the nanostructures 22, 24 continuously increases in a direction towards the substrate 110. In such embodiments, each of the nanostructures 22, 24 may have a different width and be trapezoidal in shape. In other embodiments, the sidewalls are substantially vertical (non-tapered), such that width of the fins 32 and the nanostructures 22, 24 is substantially similar, and each of the nanostructures 22, 24 is rectangular in shape.

In FIGS. 3A and 3B, isolation regions or features 36, which may be shallow trench isolation (STI) regions or features, are formed adjacent the fins 32. The isolation regions 36 may be formed by depositing an insulation material over the substrate 110, the fins 32, and nanostructures 22, 24, and between adjacent fins 32 and nanostructures 22, 24. The insulation material may be an oxide, such as silicon oxide, a nitride, the like, or a combination thereof, and may be formed by high-density plasma CVD (HDP-CVD), flowable CVD (FCVD), the like, or a combination thereof. In some embodiments, a liner (not separately illustrated) may first be formed along surfaces of the substrate 110, the fins 32, and the nanostructures 22, 24. Thereafter, a core material, such as those discussed above may be formed over the liner.

The insulation material undergoes a removal process, such as a chemical mechanical polish (CMP), an etch-back process, combinations thereof, or the like, to remove excess insulation material over the nanostructures 22, 24. Top surfaces of the nanostructures 22, 24 may be exposed and level with the insulation material after the removal process is complete.

The insulation material is then recessed to form the isolation regions 36. After recessing, the nanostructures 22, 24 and upper portions of the fins 32 may protrude from between neighboring isolation regions 36. The isolation regions 36 may have top surfaces that are flat as illustrated, convex, concave, or a combination thereof. In some embodiments, the isolation regions 36 are recessed by an acceptable etching process, such as an oxide removal using, for example, dilute hydrofluoric acid (dHF), which is selective to the insulation material and leaves the fins 32 and the nanostructures 22, 24 substantially unaltered.

FIGS. 2A through 3B illustrate one embodiment (e.g., etch last) of forming the fins 32 and the nanostructures 22, 24. In some embodiments, the fins 32 and/or the nanostructures 22, 24 are epitaxially grown in trenches in a dielectric layer (e.g., etch first). The epitaxial structures may comprise the alternating semiconductor materials discussed above, such as the first semiconductor materials and the second semiconductor materials.

In FIG. 3A and FIG. 3B, appropriate wells (not separately illustrated) may be formed in the fins 32, the nanostructures 22, 24, and/or the isolation regions 36. Using masks, an n-type impurity implant may be performed in p-type regions of the substrate 110, and a p-type impurity implant may be performed in n-type regions of the substrate 110. Example n-type impurities may include phosphorus, arsenic, antimony, or the like. Example p-type impurities may include boron, boron fluoride, indium, or the like. An anneal may be performed after the implants to repair implant damage and to activate the p-type and/or n-type impurities. In some embodiments, in situ doping during epitaxial growth of the fins 32 and the nanostructures 22, 24 may obviate separate implantations, although in situ and implantation doping may be used together.

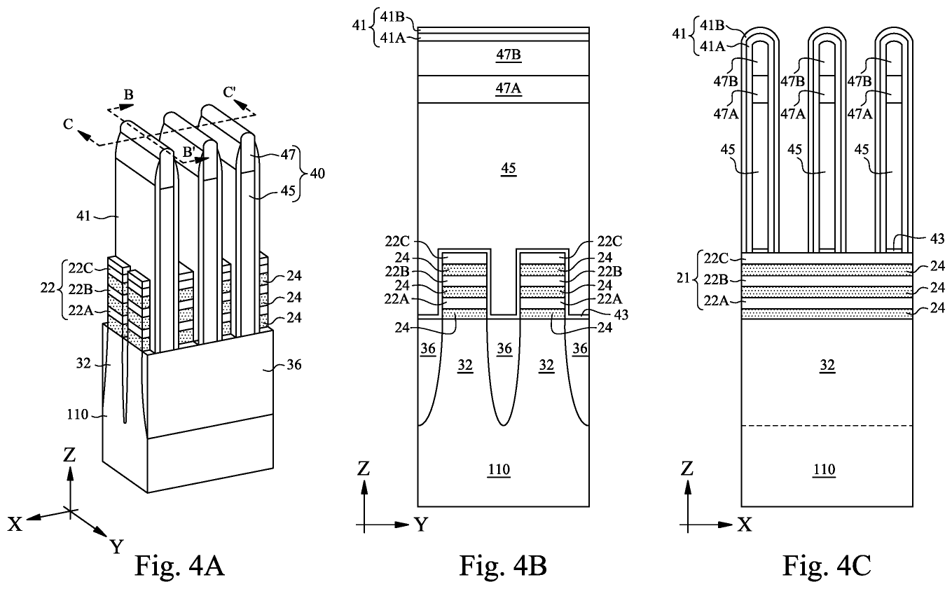

In FIGS. 4A-4C, dummy or sacrificial gate structures 40 are formed over the fins 32 and/or the nanostructures 22, 24, corresponding to act 1200 of FIG. 13. A dummy or sacrificial gate layer 45 is formed over the fins 32 and/or the nanostructures 22, 24. The dummy gate layer 45 may be or include materials that have a high etching selectivity relative to the isolation regions 36. The dummy gate layer 45 may be a conductive, semiconductive or non-conductive material and may be or include amorphous silicon, polycrystalline-silicon (polysilicon), poly-crystalline silicon-germanium (poly-SiGe), metallic nitrides, metallic silicides, metallic oxides, and metals. The dummy gate layer 45 may be deposited by physical vapor deposition (PVD), CVD, sputter deposition, or other techniques for depositing the selected material. A mask layer 47 is formed over the dummy gate layer 45, and may include, for example, silicon nitride, silicon oxynitride, or the like. In some embodiments, a gate dielectric layer 43 is formed before the dummy gate layer 45 between the dummy gate layer 45 and the fins 32 and/or the nanostructures 22, 24. In some embodiments, the mask layer 47 includes a first mask layer 47A in contact with the dummy gate layer 45, and a second mask layer 47B overlying and in contact with the first mask layer 47A. The first mask layer 47A may be or include the same or different material as that of the second mask layer 47B.

A spacer layer 41 is formed over sidewalls of the mask layer 47 and the dummy gate layer 45. The spacer layer 41 is or includes an insulating material, such as SiOCN, SiOC, SiCN or the like (or any of the materials described with reference to FIG. 1A) and may have a single-layer structure or a multi-layer structure including a plurality of dielectric layers, in accordance with some embodiments. The spacer layer 41 may be formed by depositing a spacer material layer (not shown) over the mask layer 47 and the dummy gate layer 45. Portions of the spacer material layer between dummy gate structures 40 are removed using an anisotropic etching process, in accordance with some embodiments. In some embodiments, as shown in detail in FIGS. 4B and 4C, the spacer layer 41 includes a first spacer layer 41A in contact with the nanostructure 22C, the gate dielectric layer 43, the dummy gate layer 45 and the first and second mask layers 47A, 47B. A second spacer layer 41B of the spacer layer 41 may be in contact with the first spacer layer 41A. The first spacer layer 41A may be or include the same or different material as that of the second spacer layer 41B.

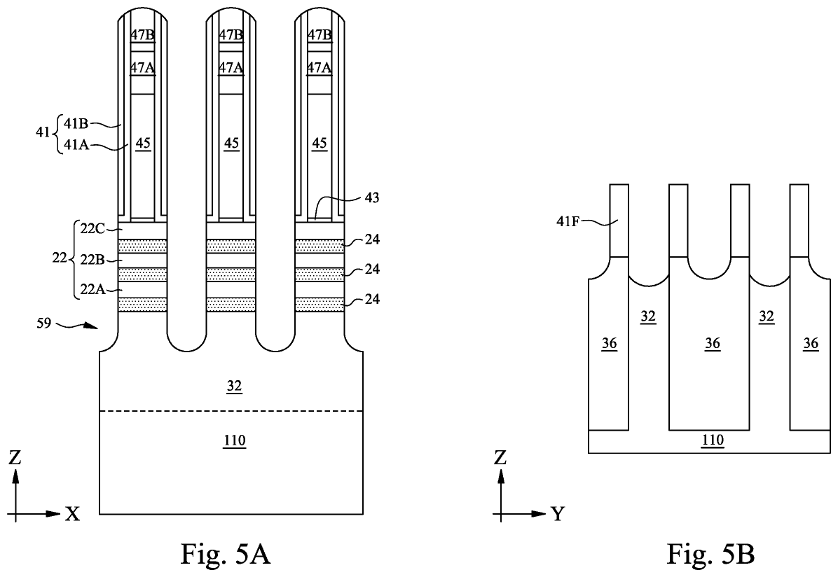

In FIGS. 5A and 5B, source/drain openings 59 are formed by performing an etching process to etch the portions of protruding fins 32 and/or nanostructures 22, 24 that are not covered by dummy gate structures 40, corresponding to act 1300 of FIG. 13. The recessing may be anisotropic, such that the portions of fins 32 directly underlying dummy gate structures 40 and the spacer layer 41 are protected and are not substantially etched. The top surfaces of the recessed fins 32 may be substantially coplanar with the top surfaces of the isolation regions 36, in accordance with some embodiments. The top surfaces of the recessed fins 32 may be lower than the top surfaces of the isolation regions 36, in accordance with some other embodiments, as depicted in FIG. 5B. FIG. 5A depicts three vertical stacks of nanostructures 22, 24 following the etching process for simplicity. In general, the etching process may be used to form fewer or additional vertical stacks of nanostructures 22, 24 over the fins 32 than those depicted. In some embodiments, the second mask layer 47B is exposed following the etching process, for example, due to removal of upper portions of the spacer layers 41A, 41B during the etching process. FIG. 5B depicts fin spacers 41F which are portions of the first and/or second spacer layers 41A, 41B that overlie the isolation regions 36 adjacent to respective fins 32.

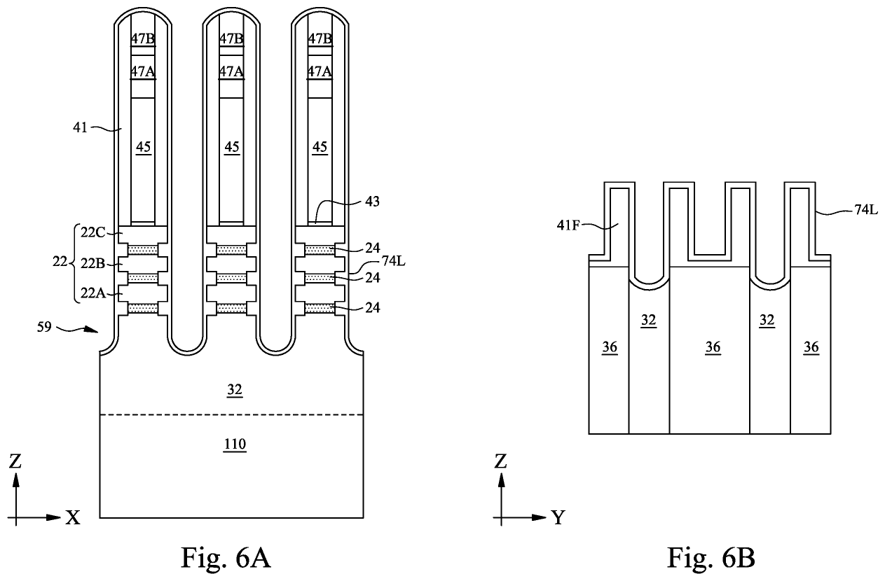

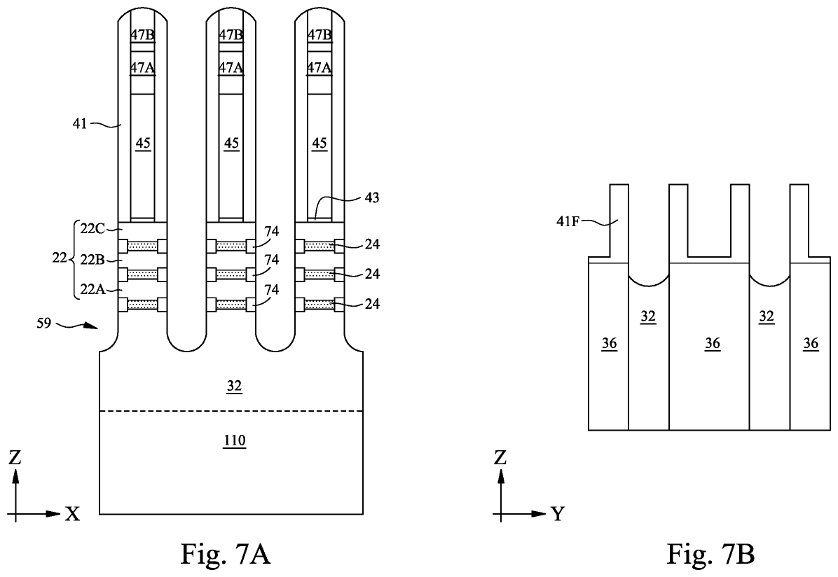

FIGS. 6A-7B depict formation of inner spacers 74 in accordance with various embodiments.

In FIGS. 6A, 6B, a selective etching process is performed to recess end portions of the nanostructures 24 exposed by openings in the spacer layer 41 without substantially attacking the nanostructures 22. After the selective etching process, recesses are formed in the nanostructures 24 at locations where the removed end portions used to be. Then, following formation of the recesses 64, an inner spacer layer 74L is formed to fill (partially or entirely) the recesses in the nanostructures 22 formed by the previous selective etching process. The inner spacer layer 74L may be a suitable dielectric material, such as silicon carbon nitride (SiCN), silicon oxycarbonitride (SiOCN), or the like, formed by a suitable deposition method such as PVD, CVD, ALD, or the like.

In FIGS. 7A and 7B, following formation of the inner spacer layer 74L, an etching process, such as an anisotropic etching process, is performed to remove portions of the inner spacer layer 74 disposed outside the recesses, for example, on sidewalls of the nanostructures 22 and the fins 32. The remaining portions of the inner spacer layer 74L (e.g., portions disposed inside the recesses in the nanostructures 24) form the inner spacers 74. The resulting structure is shown in FIG. 7A.

FIGS. 8A-8H depict formation of recrystallized source/drains 82 in accordance with various embodiments.

In FIGS. 8A, 8B, 8C, 8D, a first material layer 110A is formed in the source/drain openings 59, corresponding to act 1400 of FIG. 13. The first material layer 110A may be or include an undoped semiconductor, such as undoped silicon. The deposition may include one or more operations, such as a CVD, which may be an Ultra-High Vacuum Chemical Vapor Deposition (UHV-CVD), which allows for improved control of deposition rate and purity of the first material layer 110A. The first material layer 110A may extend to a level that is at or slightly above an upper surface of the fin 32. In some embodiments, the first material layer 110A is not formed.

Then, optional bottom insulators 800 and source/drain layers 82L are formed, corresponding to acts 1500 and 1600 of FIG. 13. The bottom insulators 800 may be formed on the first material layer 110A. In some embodiments, the bottom insulators 800 are formed in regions of the substrate 110 associated with n-type source/drains 82N. Although FIGS. 8A, 8B depict formation of a single type of source/drains 82, first and second source/drains 82N, 82P similar to described with reference to FIG. 1A may be formed in act 1600. For example, devices including n-type source/drains 82N may benefit from inclusion of the bottom insulator 800, whereas devices including p-type source/drains 82P may benefit from exclusion of the bottom insulator 800.

The first source/drains 82N and second source/drains 82P may be formed in different operations. For example, a region(s) of the substrate 110 in which second source/drains 82P are to be formed may be masked while the first source/drains 82N are formed. Then, region(s) of the substrate 110 in which first source/drains 82N have been formed may be masked while the second source/drains 82P are formed. Order of forming the first and second source/drains 82N, 82P may be reversed of that just described. Namely, second source/drains 82P may be formed prior to first source/drains 82N. In some embodiments, first source/drain layers that will be recrystallized to form the first source/drains 82N may be formed, then second source/drain layers that will be recrystallized to form the second source/drains 82P may be formed, or vice versa.

In some embodiments, prior to or following formation of the source/drain regions 82P, the optional bottom insulator 800 may be formed in the source/drain openings 59 associated with n-type nanostructure devices. Formation of the bottom insulator 800 may include a suitable deposition operation, such as an LPCVD, PECVD, ALD, or the like. The bottom insulator 800 may be or include SiN or another suitable dielectric material. Thickness of the bottom insulator 800 may be in a range of about 2 nm to about 4 nm.

Following formation of the bottom insulator 800, the source/drain regions 82N (or n-type source/drain layers) are epitaxially grown from epitaxial material(s). Due to the bottom insulator 800, the source/drain layers 82L may grow from the channels 22 without growing from the first semiconductor layer 110A. For example, as depicted in FIG. 8C, the source/drain layers 82L may have first portions 82_1 that grow outward from the channels 22, and may have second portions 82_2 that grow from the first portions 82_1.

In FIG. 8D, the source/drain layers 82L that may be associated with p-type nanostructure devices may be epitaxially grown from epitaxial material(s). Due to absence of the bottom insulator 800, the source/drain layers 82L may grow from the channels 22 and the undoped silicon layer 110A. For example, first portions 82_1 of the source/drain layers 82L may grow outward from the channels 22 and upward from the undoped silicon layer 110A, and second portions 82_2 of the source/drain layers 82L may grow from the first portions 82_1.

In some embodiments, the source/drain layers 82L associated with the n-type nanostructure devices and the p-type nanostructure devices may be formed directly on the first material layer 110A. Namely, the bottom insulator 800 may be omitted from the n-type nanostructure devices. For example, the source/drain layers 82L may be formed in a same operation simultaneously in both the n-type nanostructure devices and the p-type nanostructure devices. This may be beneficial to simplify the process, because one or more masking and patterning operations may be omitted. It may be beneficial in other embodiments to perform amorphization and SPER operations within an existing process that includes formation of the bottom insulator 800. Namely, the existing process may be modified only slightly to include the additional amorphization and SPER operations without changing the underlying structure (e.g., inclusion of the bottom insulator 800).

The source/drain layers 82L are formed such that each dummy gate structure 40 is disposed between respective neighboring pairs of the source/drain layers 82L. In some embodiments, the spacer layer 41 separates the source/drain layers 82L from the dummy gate layer 45 by an appropriate lateral distance to prevent electrical bridging to subsequently formed gates of the resulting device. The source/drain layers 82L may have surfaces raised from respective surfaces of the fins 32 and may have facets. Neighboring source/drain layers 82L may merge in some embodiments to form a singular source/drain layer 82L adjacent two neighboring fins 32.

In FIGS. 8E and 8F, amorphous source/drain layers 82A are formed by amorphizing the source/drain layers 82L, corresponding to act 1700 of FIG. 13 and act 2100 of FIG. 14.

Formation of the amorphous source/drain layers 82A or “amorphized source/drain layers 82A” may include one or more operations. Amorphizing the source/drain layers 82A may be via one or more ion implantation operations. In some embodiments, the ion implantation operation(s) includes implantation of one or more ions from implantation species that can include group III, group IV, group V, group VIII, combinations thereof or the like. For example, the group Ill ions can include ions of B, Al or Ga, the group IV ions can include ions of C, Si or Ge, the group V ions can include ions of P, As or Sb and the group VIII ions can include ions of He, Ar or Xe. The ions can be implanted at an implantation energy in a range of about 1 keV to about 60 keV. The ions can be implanted using a dosage that exceeds about 1×10¹³ cm⁻². In some embodiments, concentration of ion dopants in the source/drain layers 82A is in a range of about 1×10¹⁹ cm⁻³ to about 1×10²² cm⁻³. SPER rate may be increased (or modulated) by introducing group III and group V species in the concentration in the range described. In this range, SPER rate may be enhanced. Above about 1×10²² cm⁻³, the SPER rate may be reduced. The ions can be implanted at an implantation temperature in a range of about-150° C. to about 500° C., such as room temperature. Higher temperatures, such as above about 400° C. may reduce defect generation during the implantation process, whereas cryogenic temperatures can enhance amorphization of the source/drain layers 82L.

The amorphization may be performed in two or more separate operations, for example, to form subsequently source/drains 82P, 82N of p-type and n-type nanostructure devices, respectively. Namely, a first ion implantation operation may be performed on the source/drain layers 82A associated with p-type nanostructure devices, then a second ion implantation operation may be performed on the source/drain layers 82A associated with n-type nanostructure devices, or vice versa. In some embodiments, the first ion implantation operation may be performed to implant group Ill ions in p-type regions of the substrate 110 associated with the p-type nanostructure devices. Prior to or subsequent to the first ion implantation operation, the second ion implantation operation may be performed to implant group V ions in n-type regions of the substrate 110 associated with the n-type nanostructure devices.

In some embodiments, group IV and/or group VIII species are implanted simultaneously in the source/drain layers 82A associated with the p-type and n-type nanostructure devices. For example, because the group IV and/or group VIII species do not substantially generate excess carriers in the lattices of the source/drain layers 82A, the ion implantation thereof may be performed on both n-type and p-type regions simultaneously without masking either of the regions. This can be beneficial to simplify the process while achieving amorphization of the source/drain layers 82L.

In the description of FIGS. 8A-8F, the source/drain layers 82L are described as being formed in a crystallized state, then amorphized. In some embodiments, the source/drain layers 82L formed as described with reference to FIGS. 8A-8D are formed in an amorphous state, which may obviate further or additional amorphization thereof as described with reference to FIGS. 8E and 8F. Namely, acts 1600 and 1700 may be performed simultaneously in some embodiments. In some embodiments, the source/drain layers 82L are formed in the amorphous state, then ion implantation is performed on the source/drain layers 82L, which may be beneficial as described with reference to FIGS. 8E, 8F.

FIGS. 8G, 8H, 9A, 9B, 10A, 10B are diagrams depicting formation of recrystallized or regrown source/drains 82 in accordance with various embodiments. The embodiments described with reference to FIGS. 8G-10B may be combined. It should be understood that “recrystallized” and “regrown” do not require an initial crystallization or growth followed by a second (or third, etc.) crystallization or growth. For example, when the source/drain layers 82L are formed in an amorphous state to begin with, the “recrystallized” source/drains 82 may be crystallized for the first time. Namely, “recrystallized” includes the meaning of “crystallized for the first time.”

In FIGS. 8G, 8H, recrystallization of the amorphized source/drain layers 82A may be performed to form recrystallized source/drains 82, corresponding to operations 1800 of FIGS. 13 and 2200 and optionally 2300 of FIG. 14. The recrystallization may be performed by an operation including one or more solid-phase epitaxy regrowths (SPERs). Thermal budget of the SPER(s) may be an original thermal budget in a process flow or may include an additional anneal(s), which is beneficial to increase flexibility to implement the SPER(s) in an existing process flow. The original thermal budget, for example, may include thermal budget for forming the CESL 131, the ILD 130, the gate structure 200 or the like. For example, the SPER(s) may be performed following formation of the CESL 131, the ILD 130, the gate structure 200 or the like. In some embodiments, thermal budget for formation of the CESL 131 and/or the ILD 130 may include a temperature in a range of about 400° C. to about 800° C. for an interval in a range of about 10 minutes to about 12 hours. In some embodiments, thermal budget for formation of the gate structures 200 or “replacement gates” 200 may include a temperature in a range of about 600° C. to about 1100° C. for an interval in a range of about 0.5 minutes to about 20 minutes.

Thermal budget after formation of the gate structure 200 may be more constrained (e.g., lower temperature) to improve threshold voltage (Vt) control. In some embodiments, instead of or in addition to the original thermal budget, one or more additional anneals may be performed prior to forming the CESL 131, e.g., while the source/drain layer 82A is exposed in the source/drain opening 59.

In some embodiments, as depicted in FIGS. 8G, 8H, the SPER(s) may be performed via an additional anneal(s) while the source/drain layer 82A is exposed (e.g., prior to formation of the CESL 131). The anneal or anneals may include one or more of a rapid thermal annealing (RTA), furnace anneal, millisecond anneal, microsecond anneal, flash anneal, laser anneal, melting laser anneal, combinations thereof or the like. Performing the anneal(s) can repair or prevent (111) or other directional stacking faults and recover or improve strain of the recrystallized source/drain 82, for example, due to the SPER along the (100) direction being about 1 order faster than along the (111) direction. Some anneal operations that include higher temperature and shorter time (e.g., laser anneal) can dissolve interstitial clusters to increase dopant activation level, for example, by dopant substitution. In some embodiments, the anneal(s) are performed including a temperature in a range of about 600° C. to about 1200° C. for an interval in a range of about 1×10⁻¹⁰ seconds to about 1×10⁶ seconds. Dopant solubility limit is a maximum concentration that can be achieved in equilibrium with a host lattice. Performing the one or more SPERS can result in active concentrations well above the dopant solubility limit, which can reduce resistance of the recrystallized source/drains 82.

In some embodiments, the anneal(s) performed prior to formation of the CESL 131 may recrystallize the source/drains 82 partially or fully. FIGS. 8G, 8H depict partial formation of the recrystallized source/drains 82 via one or more anneals performed while the source/drain layer 82A is exposed. In some embodiments, the formation of the recrystallized source/drains 82 is completed by the SPER(s) performed while the source/drain layers 82A are exposed.

As depicted in FIGS. 8G, 8H, recrystallization of the source/drain layers 82A overlying the bottom insulator 800 (FIG. 8G) may complete prior to recrystallization of the source/drain layers 82A in which the bottom insulator 800 is not present (FIG. 8H). This may be due to additional height of the source/drain layers 82A in which the bottom insulator 800 is not present. Namely, the source/drain layers 82A for which the bottom insulator 800 is not present may have additional height equal to about thickness of the bottom insulator 800. As a result, the recrystallization of the source/drain layers 82A having the additional height may complete after the recrystallization of the source/drain layers 82A that overlie the bottom insulator 800. In some embodiments, the recrystallized source/drain 82 over the bottom insulator 800 may be completed by a first SPER while the recrystallized source/drain 82 for which the bottom insulator 800 is omitted may be completed by a second SPER following the first SPER.

Formation of the recrystallized source/drains 82 either partially or fully may include a single SPER or two or more SPERs that are performed prior to formation of the CESL 131, such as while the source/drain layers 82A are exposed.

In some embodiments, the SPER(s) described with reference to FIGS. 8G, 8H are omitted. Such embodiments may correspond to performing recrystallization of the source/drain layers 82A within the original thermal budget, as described previously. This is depicted in FIG. 14 by dashed boxes for acts 2200 and 2300.

FIGS. 9A and 9B depict formation of the CESL 131 and the ILD 130. The ILD 130 may be formed covering the source/drain layers 82A and/or the recrystallized source/drains 82 and abutting the spacer layer(s) 41. In some embodiments, the CESL 131 is formed prior to forming the ILD 130. The CESL 131 may be formed by depositing a conformal thin layer of a dielectric material different from that of the ILD 130, such as one or more of SiN, SiCN, SiC, SiOC, SiOCN, HfO2, ZrO2, ZrAlOx, HfAlOx, HfSiOx, Al2O3, or other suitable material. Following deposition of the CESL 131, the ILD 130 may be deposited by a suitable process, such as a blanket deposition process, including PVD, CVD, ALD, or the like. The material of the ILD 130 may include silicon dioxide or a low-k dielectric material (e.g., a material having a dielectric constant (k-value) lower than the k-value (about 3.9) of silicon dioxide). The low-k dielectric material may include silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOxCy), Spin-On-Glass (SOG) or a combination thereof. The ILD may be deposited by spin-on coating, CVD, Flowable CVD (FCVD), PECVD, PVD, or another deposition process.

In some embodiments, completion of recrystallization of the source/drain layers 82A to form the recrystallized source/drains 82 can be performed simultaneously and/or following formation of the CESL 131 and the ILD 130, for example, using the thermal budget associated with each process, corresponding to act 2400 of FIG. 14. In some embodiments, the source/drain layers 82A are not completely recrystallized during the formation of the CESL 131 and/or the ILD 130, but instead are partially recrystallized. In some embodiments, thermal budget for formation of the CESL 131 and/or the ILD 130 may include a temperature in a range of about 400° C. to about 800° C. for an interval in a range of about 10 minutes to about 12 hours. Act 2400 may be optional as depicted by a dashed box in FIG. 14. For example, in embodiments in which the recrystallized source/drains 82 are completed prior to formation of the CESL 131, act 2400 may be omitted.

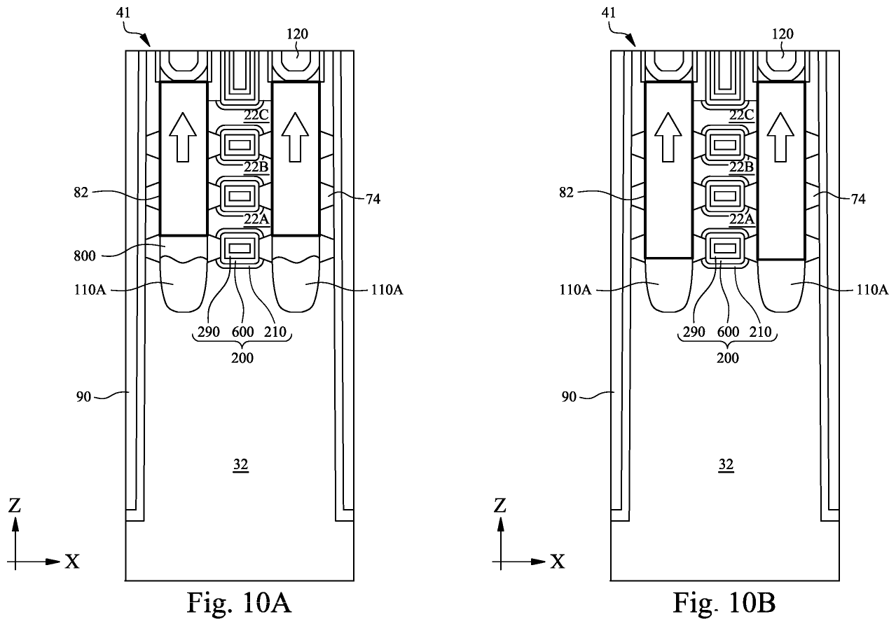

In FIGS. 10A, 10B, active gate structures 200 are formed. A planarization process, such as a chemical mechanical polishing (CMP) process, is performed on the ILD 130 and the ESL 131. The hard masks 47A, 47B and portions of the gate spacers 41 are also removed in the planarization process. After the planarization process, the dummy gate layers 45 are exposed. The top surfaces of the ILD 130 and the ESL 131 may be coplanar with the top surfaces of the dummy gate layers 45 and the gate spacers 41.

Next, the dummy gate layer 45 is removed in an etching process, so that recesses are formed. In some embodiments, the dummy gate layer 45 is removed by an anisotropic dry etch process. For example, the etching process may include a dry etch process using reaction gas(es) that selectively etch the dummy gate layer 45 without etching the spacer layer 41. The dummy gate dielectric 43, when present, may be used as an etch stop layer when the dummy gate layer 45 is etched. The dummy gate dielectric 43 may then be removed after the removal of the dummy gate layer 45.

The nanostructures 24 are removed to release the nanostructures 22. After the nanostructures 24 are removed, the nanostructures 22 form a plurality of nanosheets that extend horizontally (e.g., parallel to a major upper surface of the substrate 110). In some embodiments, the nanostructures 24 are removed by a selective etching process using an etchant that is selective to the material of the nanostructures 24, such that the nanostructures 24 are removed without substantially attacking the nanostructures 22. In some embodiments, the etching process is an isotropic etching process using an etching gas, and optionally, a carrier gas, where the etching gas comprises F2 and HF, and the carrier gas may be an inert gas such as Ar, He, N2, combinations thereof, or the like.

In some embodiments, the nanostructures 24 are removed and the nanostructures 22 are patterned to form channel regions of both PFETs and NFETs. However, in some embodiments the nanostructures 24 may be removed and the nanostructures 22 may be patterned to form channel regions of NFETs, and nanostructures 22 may be removed and the nanostructures 24 may be patterned to form channel regions of PFETs. In some embodiments, the nanostructures 22 may be removed and the nanostructures 24 may be patterned to form channel regions of NFETs, and the nanostructures 24 may be removed and the nanostructures 22 may be patterned to form channel regions of PFETs. In some embodiments, the nanostructures 22 may be removed and the nanostructures 24 may be patterned to form channel regions of both PFETs and NFETs.

In some embodiments, the nanosheets 22 are reshaped (e.g. thinned) by a further etching process to improve gate fill window. The reshaping may be performed by an isotropic etching process selective to the nanosheets 22. After reshaping, the nanosheets 22 may exhibit the dog bone shape in which middle portions of the nanosheets 22 are thinner than peripheral portions of the nanosheets 22 along the X direction (see FIG. 10C, for example).

Then, replacement gates 200 are formed. The gate structures 200 may be formed by a series of deposition operations, such as ALD cycles, that deposit the various layers of the gate structure 200 in the openings, described below with reference to FIG. 12.

In some embodiments, thermal budget for formation of the gate structures 200 or “replacement gates” 200 may include a temperature in a range of about 600° C. to about 1100° C. for an interval in a range of about 0.5 minutes to about 20 minutes.

FIG. 12 is a detailed view of a portion of the gate structure 200. The gate structure 200 generally includes the interfacial layer (IL, or “first IL” below) 210, at least one gate dielectric layer 600, the work function metal layer 900, and the gate fill layer 290. In some embodiments, each replacement gate 200 further includes at least one of a second interfacial layer 240 or a second work function layer 700.

With reference to FIG. 12, in some embodiments, the first IL 210 includes an oxide of the semiconductor material of the substrate 110, e.g. silicon oxide. In other embodiments, the first IL 210 may include another suitable type of dielectric material. The first IL 210 has a thickness in a range between about 5 angstroms and about 50 angstroms.

Still referring to FIG. 12, the gate dielectric layer 600 is formed over the first IL 210. In some embodiments, an atomic layer deposition (ALD) process is used to form the gate dielectric layer 600 to control thickness of the deposited gate dielectric layer 600 with precision. In some embodiments, the ALD process is performed using between about 40 and 80 deposition cycles, at a temperature range between about 200 degrees Celsius and about 300 degrees Celsius. In some embodiments, the ALD process uses HfCl4 and/or H2O as precursors. Such an ALD process may form the first gate dielectric layer 220 to have a thickness in a range between about 10 angstroms and about 100 angstroms.

In some embodiments, the gate dielectric layer 600 includes a high-k dielectric material, which may refer to dielectric materials having a high dielectric constant that is greater than a dielectric constant of silicon oxide (k≈3.9). Exemplary high-k dielectric materials include HfO₂, HfSiO, HfSiON, HfTaO, HfTiO, HfZrO, ZrO₂, Ta₂O₅, or combinations thereof. In other embodiments, the gate dielectric layer 600 may include a non-high-k dielectric material such as silicon oxide. In some embodiments, the gate dielectric layer 600 includes more than one high-k dielectric layer, of which at least one includes dopants, such as lanthanum, magnesium, yttrium, or the like, which may be driven in by an annealing process to modify threshold voltage of the nanostructure devices 20A, 20B.

With further reference to FIG. 12, the second IL 240 is formed on the gate dielectric layer 600, and the second work function layer 700 is formed on the second IL 240. The second IL 240 promotes better metal gate adhesion on the gate dielectric layer 600. In many embodiments, the second IL 240 further provides improved thermal stability for the gate structure 200, and serves to limit diffusion of metallic impurity from the work function metal layer 900 and/or the work function barrier layer 700 into the gate dielectric layer 600. In some embodiments, formation of the second IL 240 is accomplished by first depositing a high-k capping layer (not illustrated for simplicity) on the gate dielectric layer 600. The high-k capping layer comprises one or more of the following: HfSiON, HfTaO, HfTiO, HfTaO, HfAlON, HfZrO, or other suitable materials, in various embodiments. In a specific embodiment, the high-k capping layer comprises titanium silicon nitride (TiSiN). In some embodiments, the high-k capping layer is deposited by an ALD using about 40 to about 100 cycles at a temperature of about 400 degrees C. to about 450 degrees C. A thermal anneal is then performed to form the second IL 240, which may be or comprise TiSiNO, in some embodiments. Following formation of the second IL 240 by thermal anneal, an atomic layer etch (ALE) with artificial intelligence (Al) control may be performed in cycles to remove the high-k capping layer while substantially not removing the second IL 240. Each cycle may include a first pulse of WCl₅, followed by an Ar purge, followed by a second pulse of O₂, followed by another Ar purge. The high-k capping layer is removed to increase gate fill window for further multiple threshold voltage tuning by metal gate patterning. In some embodiments, the thermal anneal includes a SPER that partially or fully completes the recrystallization of the source/drain layers 82A.

Further in FIG. 12, after forming the second IL 240 and removing the high-k capping layer, the work function barrier layer 700 is optionally formed on the gate structure 200, in accordance with some embodiments. The work function barrier layer 700 is or comprises a metal nitride, such as TiN, WN, MON, TaN, or the like. In a specific embodiment, the work function barrier layer 700 is TIN. The work function barrier layer 700 may have thickness ranging from about 5 A to about 20 A. Inclusion of the work function barrier layer 700 provides additional threshold voltage tuning flexibility. In general, the work function barrier layer 700 increases the threshold voltage for NFET transistor devices, and decreases the threshold voltage (magnitude) for PFET transistor devices.

The work function metal layer 900, which may include at least one of an N-type work function metal layer, an in-situ capping layer, or an oxygen blocking layer, is formed on the work function barrier layer 700, in some embodiments. The N-type work function metal layer is or comprises an N-type metal material, such as TiAlC, TiAl, TaAlC, TaAl, or the like. The N-type work function metal layer may be formed by one or more deposition methods, such as CVD, PVD, ALD, plating, and/or other suitable methods, and has a thickness between about 10 A and 20 A. The in-situ capping layer is formed on the N-type work function metal layer. In some embodiments, the in-situ capping layer is or comprises TIN, TiSiN, TaN, or another suitable material, and has a thickness between about 10 A and 20 A. The oxygen blocking layer is formed on the in-situ capping layer to prevent oxygen diffusion into the N-type work function metal layer, which would cause an undesirable shift in the threshold voltage. The oxygen blocking layer is formed of a dielectric material that can stop oxygen from penetrating to the N-type work function metal layer, and may protect the N-type work function metal layer from further oxidation. The oxygen blocking layer may include an oxide of silicon, germanium, SiGe, or another suitable material. In some embodiments, the oxygen blocking layer is formed using ALD and has a thickness between about 10 A and about 20 A.

FIG. 12 further illustrates the metal core layer 290. In some embodiments, a glue layer (not separately illustrated) is formed between the oxygen blocking layer of the work function metal layer and the metal core layer 290. The glue layer may promote and/or enhance the adhesion between the metal core layer 290 and the work function metal layer 900. In some embodiments, the glue layer may be formed of a metal nitride, such as TIN, TaN, MON, WN, or another suitable material, using ALD. In some embodiments, thickness of the glue layer is between about 10 A and about 25 A. The metal core layer 290 may be formed on the glue layer, and may include a conductive material such as tungsten, cobalt, ruthenium, iridium, molybdenum, copper, aluminum, or combinations thereof. In some embodiments, the metal core layer 290 may be deposited using methods such as CVD, PVD, plating, and/or other suitable processes. In some embodiments, a seam 510, which may be an air gap, is formed in the metal core layer 290 vertically between the channels 22A, 22B, 22C. In some embodiments, the metal core layer 290 is conformally deposited on the work function metal layer 900. The seam 510 may form due to sidewall deposited film merging during the conformal deposition. In some embodiments, the seam 510 is not present between the neighboring channels 22A, 22B, 22C.

Referring again to FIGS. 10A, 10B, following formation of the gate structures 200, source/drain contact openings may be formed in the ILD 130 and source/drain contacts 120 may be formed in the source/drain contact openings, corresponding to act 2500 of FIG. 14. The resulting structure is shown in FIGS. 10A, 10B. Silicide regions 118 (see FIG. 1A and FIG. 11) and the source/drain contacts 120 are formed on the source/drain regions 82N, 82P.

In some embodiments, the silicide layers 118 are formed prior to formation of the source/drain contacts 120. For example, an N-type or P-type metal layer may be formed as a conformal thin layer over exposed portions of the source/drain regions 82N, 82P. The metal layer may be or include one or more of Ni, Co, Mn, W, Fe, Rh, Pd, Ru, Pt, Ir, Os or the like. In some embodiments, the metal layer is or includes one or more of Ti, Cr, Ta, Mo, Zr, Hf, Sc, Ys, Ho, Tb, Gd, Lu, Dy, Er, Yb or another suitable material. Following formation of the metal layer, the silicide layers 118 may be formed by annealing the device 10. Following the anneal, the silicide layers 118 may be or include one or more of NiSi, CoSi, MnSi, Wsi, FeSi, RhSi, PdSi, RuSi, PtSi, IrSi, OsSi, TiSi, CrSi, TaSi, MoSi, ZrSi, HfSi, ScSi, Ysi, HoSi, TbSI, GdSi, LuSi, DySi, ErSi, YbSi or the like. Silicide of the silicide layers 118 may diffuse into regions below the ESL 131. Thickness of the silicide layers 118 may be in a range of about 1 nm to about 10 nm. Below about 1 nm, contact resistance may be too high. Above about 10 nm, the silicide layers 118 may short with the channels 22B. In some embodiments, the anneal that forms the silicide layers 118 includes a SPER that partially or fully completes the recrystallization of the source/drain layers 82A.

Following formation of the silicide layers 118, the source/drain contacts 120 are formed by filling the openings over the source/drain regions 82N, 82P with, for example, a liner layer and a fill layer. In some embodiments, the source/drain contacts 120 are formed by depositing a material that is or includes a conductive material such as Co, W, Ru, combinations thereof, or the like. In some embodiments, the source/drain contacts 120 are or include a Co-, W- or Ru-based compound or alloy including one or more elements, such as Zr, Sn, Ag, Cu, Au, Al, Ca, Be, Mg, Rh, Na, Ir, W, Mo, Zn, Ni, K, Co, Cd, Ru, In, Os, Si, Ge, Mn, combinations thereof, or the like. The source/drain contacts 120 land on the silicide layer 118 and are in contact with the ESL 131. Description of the device 10 and illustration thereof in many of the figures is given with reference to GAAFETs including vertical stacks of the nanostructures 22. In some embodiments, the silicide layers 118 and the source/drain contacts 120 are formed in and on source/drain regions 82N, 82P of FinFET or planar devices.

FIG. 11 depicts a diagrammatic cross-sectional view of an IC device 10 that includes nanostructure devices 20A, 20B, 20C in accordance with various embodiments. The IC device 10 may be an embodiment of the devices depicted in FIGS. 1A and 10A, 10B, and like reference numerals refer to like features.

In FIG. 11, the IC device 10 includes the recrystallized source/drains 82. In some embodiments, one or more visible interfaces 8211, 8212 are present between a first portion 820A, a second portion 820B and a third portion 820C of the recrystallized source/drains 82. For example, a first visible interface 8211 may be present between the first portion 820A and the second portion 820B and a second visible interface 8212 may be present between the second portion 820B and the third portion 820C. The visible interfaces 8211, 8212 may be present due to halting the SPER partway through recrystallization of the source/drain layers 82A.

When the SPER of a continuous amorphous layer, such as the source/drain layer 82A, is halted partway through the layer and then continues later, several characteristics may be affected around interfaces between the various recrystallized portions. Measurable characteristics that may be affected can include one or more of crystallographic defect density, dopant distribution, strain and/or stress, electrical characteristics, interface sharpness, material composition, optical properties, mechanical properties or the like. For example, an increased density of crystallographic defects may be present at the interfaces where the process was halted and then restarted. For example, crystallographic defect density in the visible interfaces 8211, 8212 may exceed those in the first, second and/or third portions 820A, 820B, 820C. The defects may include dislocations, stacking faults, point defects or the like. The concentration of dopants may vary across the visible interfaces 8211, 8212, resulting in one or more dopant pile-ups or depletion regions. For example, dopant concentration may be different in the first portion 820A than in the second portion 820B or in the second portion 820B than in the third portion 820C. Thermal cycling may induce strain or stress around the visible interfaces 8211, 8212, which may cause lattice distortions. Variations in dopant distribution and defect density may result in changes in electrical properties such as carrier mobility, carrier lifetime, and resistivity. Abruptness of the interface may be visible using transmission electron microscopy (TEM) or high-resolution X-ray reflectivity (XRR), which may show a less sharp interface due to the halt in the process. Impurities or secondary phases may form at the visible interfaces 8211, 8212 during the halt. Variations in the defect density and strain at the interface may alter optical properties of the material. The visible interfaces 8211, 8212 may have different mechanical properties, such as hardness or brittleness, than those of the first, second and third portions 820A, 820B, 820C.

Additional SPER(s) may be performed following formation of the gate structures 200 and/or the source/drain contacts 120, corresponding to act 2600 of FIG. 14. In many embodiments, thermal budget after formation of the gate structures 200 is more constrained (e.g., lower temperature) to improve Vt control.

In the above, the recrystallized source/drains 82 of p-type devices and the recrystallized source/drains 82 of n-type devices may have differences. For example, differences in dopant species and/or ion implantation processes that implant the different dopant species may result in different concentrations or numbers of stacking faults in the recrystallized source/drains 82. For example, a first recrystallized source/drain 82 associated with a p-type device and including group Ill dopants may have a number of stacking faults that exceeds that of a second recrystallized source/drain 82 associated with an n-type device and including group V dopants. In another example, the second recrystallized source/drain 82 may have a number of stacking faults that exceeds that of the first recrystallized source/drain 82. Other such differences may include concentration and/or distribution of the stacking faults, concentration, number and/or distribution of dislocations, or the like. As such, a device may include a substrate (e.g., the substrate 110 or fin 32), a first stack of semiconductor channels 22 on the substrate and a second stack of semiconductor channels 22 on the substrate. A first recrystallized source/drain 82 of a first type (e.g., p-type) may abut the semiconductor channels 22 of the first stack and a second recrystallized source/drain 82 of a second type (e.g., n-type) different than the first type may abut the semiconductor channels 22 of the second stack. As described, the second recrystallized source/drain 82 may have a first number of stacking faults that exceeds a second number of stacking faults of the second recrystallized source/drain 82.

Following formation of the source/drain contacts 120, gate contacts (or gate vias; not separately depicted) may be formed to electrically couple to the gate structures 200. An interconnect structure may then be formed over the source/drain contacts 120 and the gate contacts. The interconnect structure may include a plurality of dielectric layers (including, for example, a second ILD) having metallic features, including conductive traces and conductive vias, embedded therein. The metallic features may form electrical connection(s) between devices on the substrate 110, such as the nanostructure devices 20A, 20B, 20C, as well as to IC devices external to the IC device 10.

Embodiments may provide advantages. The amorphization via ion implantation followed by one or more SPERs allow for reduction in dislocation and/or stacking fault defects and improved dopant activation, which can reduce source/drain resistance and improve strain in the channels. Selection of ion implantation species and anneal number and sequence of the SPER operations are flexible, which is beneficial for including the embodiments in existing processes.

In accordance with at least one embodiment, a method includes: forming a stack of nanostructures over a substrate; forming a source/drain opening adjacent the stack of nanostructures; forming a semiconductor layer in the source/drain opening; forming an amorphous semiconductor layer by performing an ion implantation on the semiconductor layer; and forming a recrystallized source/drain by annealing the amorphous semiconductor layer.

In accordance with at least one embodiment, a method includes: forming a stack of nanostructures over a substrate; forming a source/drain opening adjacent the stack of nanostructures; forming a semiconductor layer in the source/drain opening; forming an amorphous semiconductor layer by amorphizing the semiconductor layer; and forming a source/drain by performing solid-phase epitaxy regrowth on the amorphous semiconductor layer.

In accordance with at least one embodiment, a device includes: a substrate; a first stack of semiconductor channels on the substrate; a second stack of semiconductor channels on the substrate; a first recrystallized source/drain of a first type abutting the semiconductor channels of the first stack; and a second recrystallized source/drain of a second type different than the first type abutting the semiconductor channels of the second stack, the first recrystallized source/drain having a first number of stacking faults that exceeds a second number of stacking faults of the second recrystallized source/drain.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a stack of nanostructures over a substrate;
forming a source/drain opening adjacent the stack of nanostructures;
forming a semiconductor layer in the source/drain opening;
forming an amorphous semiconductor layer by performing an ion implantation on the semiconductor layer; and
forming a recrystallized source/drain by annealing the amorphous semiconductor layer.

2. The method of claim 1, wherein the annealing the amorphous semiconductor layer includes performing an anneal while an upper surface of amorphous semiconductor layer is exposed.

3. The method of claim 2, wherein the performing an anneal includes performing at least two different anneals.

4. The method of claim 2, wherein the performing an anneal terminates after the amorphous semiconductor layer is fully regrown.

5. The method of claim 1, wherein the annealing the amorphous semiconductor layer includes annealing the amorphous semiconductor layer after at least one of:
forming a contact etch stop layer on the amorphous semiconductor layer;
forming an interlayer dielectric on the contact etch stop layer; or
forming a replacement gate that wraps around the nanostructures of the stack of nanostructures.

6. The method of claim 5, further comprising performing solid-phase epitaxial regrowth on the amorphous semiconductor layer via a second anneal prior to the annealing the amorphous semiconductor layer.

7. The method of claim 6, wherein the performing solid-phase epitaxial regrowth terminates prior to the amorphous semiconductor layer being fully regrown.

8. A method, comprising:
forming a stack of nanostructures over a substrate;
forming a source/drain opening adjacent the stack of nanostructures;
forming a semiconductor layer in the source/drain opening;
forming an amorphous semiconductor layer by amorphizing the semiconductor layer; and
forming a source/drain by performing solid-phase epitaxy regrowth on the amorphous semiconductor layer.

9. The method of claim 8, wherein the amorphizing the semiconductor layer includes implanting ions, the ions being of a group IV, group III, group V or group VIII species.

10. The method of claim 9, wherein the implanting the ions includes implanting the ions at a dosage that exceeds about 1×10¹³ cm⁻².

11. The method of claim 9, wherein the implanting the ions includes implanting the ions at an energy that is in a range of about 1 kilo-electron-volt (keV) to about 60 keV.

12. The method of claim 9, wherein the implanting the ions includes implanting the ions at a temperature in a range of about −150° C. to about 500° C.

13. The method of claim 8, wherein the performing solid-phase epitaxy regrowth includes performing at least one of rapid thermal annealing, furnace annealing, millisecond annealing, microsecond annealing, flash annealing, laser annealing or melting laser annealing.

14. The method of claim 8, wherein the performing solid-phase epitaxial regrowth includes performing annealing at a temperature in a range of about 400° C. to about 800° C. for a period in a range of about 10 minutes to about 12 hours.

15. A device, comprising:
a substrate;
a first stack of semiconductor channels on the substrate;
a second stack of semiconductor channels on the substrate;
a first recrystallized source/drain of a first type abutting the semiconductor channels of the first stack; and
a second recrystallized source/drain of a second type different than the first type abutting the semiconductor channels of the second stack, the first recrystallized source/drain having a first number of stacking faults that exceeds a second number of stacking faults of the second recrystallized source/drain.

16. The device of claim 15, wherein:
the first recrystallized source/drain includes ion implants of a first species; and
the second recrystallized source/drain includes ion implants of a second species different than the first species.

17. The device of claim 15, further comprising a dielectric layer between the second recrystallized source/drain and the substrate, wherein a bottom surface of the second recrystallized source/drain is at a level offset from a bottom surface of the first recrystallized source/drain by about a thickness of the dielectric layer.

18. The device of claim 15, wherein a visible interface is present between a first portion of the first recrystallized source/drain and a second portion of the first recrystallized source/drain.

19. The device of claim 18, wherein dopant concentration is different in the first portion than in the second portion.

20. The device of claim 18, wherein crystallographic defect density in the visible interface exceeds those in the first portion and the second portion.
